(19) United States
(12) Patent Application Publication
(10) Pub. No.: US 2008/0085368 A1
(43) Pub. Date: Apr. 10, 2008

(54) Method and Apparatus for Coating a Substrate

(76) Inventor: Ben M. Gauthier, Washington, DC (US)

Correspondence Address: BAKER DONELSON BEARMAN CALDWELL & BERKOWITZ, PC, 555 11TH STREET, NW, 6TH FLOOR, WASHINGTON, DC, 20004, US

(21) Appl. No.: 11/539,927

(22) Filed: Oct. 10, 2006

(51) Int. Cl. B05C 13/02; B05D 3/02; H05H 1/24; C23C 16/00; C23C 14/28

(52) U.S. Cl. 427/314; 427/569; 427/595; 118/715; 118/58

(57) ABSTRACT

A method of coating a substrate comprises pre-heating an area of a surface layer of the substrate for a duration of time, and depositing a coating precursor material over the heated area within a preset time window of the heating step, wherein the temperature of the heated area remains suitable for enhancing the bond between the coating precursor material and the substrate. The pre-heating and coating steps may be repeated many times at desired frequency and over the entire area of the surface of the substrate, and may be conducted in a low pressure environment or vacuum. Also disclosed is an apparatus the inventive method which comprises a heating component, a depositing component for depositing intermittently a coating precursor material to the substrate, and a suitable controlling component.

### FIELD OF THE INVENTION

The present invention is directed to coating technology, and more particularly to methods and devices that form a coating over another, substrate material or to form a free standing form. This technology is referred to as Pulsed Preheating-Pulsed Coating (PPPC) technology.

### BACKGROUND OF THE INVENTION

The coating of a substrate with another material is a powerful manufacturing process that enables a solid surface or structure to be built up from successive layers of material deposited by one or more of thermal, chemical and mechanical means. Coating methods are used to alter the surface or other properties and characteristics of the final product, or in some cases, to simply form an entire structure or product from successive layers of deposited material. A variety of coating methods are used to deposit various coating material precursors. Examples of coating methods are: High Velocity Oxygen Fuel (HVOF), High Velocity Air Fuel (HVAF), plasma spray, laser sintering/cladding, kinetic metallization, electric arc deposition and detonation coating. In general the coating processes in all the above methods include injecting coating precursor material or particles into a gas stream for acceleration and, in most cases, heating of the particles to their melting point using one of various energy sources (combustion, laser, electric arc, etc.). Upon impact with the substrate, the particles, if molten, splatter onto the surface and solidify, or if still solid, plastically collide with the substrate and embeds in it. Successive bombardment with particles results in a built up coating layer.

While each of these approaches has a unique set of advantages and disadvantages, they all face similar challenges. The main challenge is to form a strong bond between the base layer (or substrate) and the newly applied layer of material and to deposit coating material with high density and low porosity. The goal typically is to have the properties of the coating approach the properties of the same material in full-density bulk form. However, depending on the material system of interest, successful coatings often fall far from these standards. For example, for the cermet WC10Co (tungsten carbide 10% cobalt), HVOF coatings are considered to be excellent when they have porosity <1% and hardness of 1000 HV, while optimal properties in bulk form may approach 0% porosity and 2000 HV hardness. The disparity between the material properties of the as HVOF coated material and the bulk properties leave much to be desired from coating application standpoint.

While some materials are easier than others to coat, in general, the properties of the coated layer and the bond strength are sensitive to the state of the impacting particles and the state of the surface of the substrate. For the impacting particles, the important parameters are generally the velocity/momentum, temperature and physical state (i.e. solid or liquid/molten). Significant parameters on the base surface generally include cleanliness, roughness, hardness, temperature and physical state. These two areas of attention are generally referred to as particle delivery parameters and surface preparation, respectively, and much attention has been paid to each in order to obtain better material properties. In nearly all instances, the bond between the impacting particles and the surface will be enhanced with higher particle velocity and temperature. Optimal surface properties are less obvious because they depend on the bonding mechanism. For bonding between a molten particle and a solid surface, a rougher surface finish will allow for more interlocking or grip, resulting in a stronger bond. For bonding between molten particles and a molten surface, which results in the molten particles molecularly, e.g. metallurgically mixing or fusing with molten surface material and much stronger bonding, bond strength does not rely on surface roughness.

There are many techniques available for forming molecular/metallurgical bonding between two materials, such as welding and cladding. Unfortunately, existing techniques use excessive energy to sustain a molten state at coated substrate, which introduces many challenges with regard to practical coating processes. The first challenge relates to structural integrity, as excessively high temperatures of the substrates that need to be obtained to assure molecular/metallurgical bonding are not suitable for coating thin, small, or otherwise geometrically complicated parts. Rather, it is necessary to have a heat conduction path or a mass sufficient to sustain the temperature gradient without melting the bulk part or warping/bending the part as a result of thermal stresses. In the laser cladding process, the melt pool of coated material is generated by a high power laser (CO₂ or high power diode lasers for example); particles are then delivered to this melt pool and welded to the surface. During this process a thick deposit is created and the substrate material is heated to very high temperatures. As an example, steel plates as thick as ½ inches can be warped when coated using laser cladding. A second concern is that many alloys and their desired microstructures are thermally sensitive, and as a consequence, exposure to excessive temperatures, even for a brief period of time, could degrade the properties of the coated and/or base material.

U.S. Pat. No. 6,197,386 discloses a laser-assisted air plasma spraying (LAAPS) method, which combines surface preparation by laser preheating with air plasma spray coating, and achieves a high strength bond and good coating quality. Use of laser preheating of the surface just before deposition of plasma heated particles of the precursor powder allows molten particles to mix with the molten layer on the substrate, creating a molecular/metallurgical bond between the molten layer of the substrate and the coating. In the LAAPS method, the surface is preheated by the laser irradiation so that it will cause melting of the substrate layer just before molten particles that are heated and accelerated by the gas of plasma spray (PS) impinge onto this molten surface. For effective LAAPS coatings, however, the surface should remain molten or close to the molten state during the time it takes the particle beam created by PS to pass over it. This localized substrate heating is accomplished by the laser. The heating depth requirement will vary as a function of thermal capacity and thermal conductivity of the substrate, as well as heat flux from the substrate to the surrounding gas. The LAAPS type system requires a 0.1 mm layer of the substrate to be melted during the deposition, which, because of conduction, results in a 2 to 10 mm deep layer of material that effectively is heated to very high temperatures. As in the case of laser cladding, such substrate overheating may cause alloy degradation, and if the LAAPS method is applied to small or relatively thin (few millimeters) parts, it will cause warping due to stress induced by uneven heating.

U.S. Pat. No. 3,310,423 describes the use of pulsed laser heating to enhance the coating properties of a flame spray process without the excessive thermal load on the surface. This technique relies on a high peak flux pulsed laser to overheat the impinging particles such that upon impact with the substrate surface, they conduct sufficient heat to additionally melt the surface to create a molecular/metallurgical bond. Another technique described in this patent deposits a single layer and then instantaneously heats the single layer with a laser pulse to a softening point, followed by the spraying of another layer, with subsequent heat treatment as well. For each of these two embodiments, the objective is to have both a molten surface and molten particles after the impact in order to facilitate molecular/metallurgical bonding. In each of the two mentioned embodiments, however, the technique is limited in its usefulness by inefficient use of laser energy. The primary advantage of using a laser as an additional source of energy lies in the high heat flux rates that a laser is capable of producing, which can overwhelm the conduction rates that resolve internal thermal gradients within the base material. In the first embodiment, the additional laser energy, while ultimately intended to melt the substrate surface, is passed first to the impinging particles at the high heat flux rates. Upon particle impact, however, this surplus energy is delivered to the desired base material at heat flux rates governed by conduction, which are the same rates that govern the heat removal from the surface of the base material. The primary effect of such an approach will be comparable to a slightly higher temperature flame spray process, and any additional effect as described on melting the surface layer would necessarily come with significant thermal loading. In other words, due to the high conduction rate resulting in heat removal from the substrate surface, a higher thermal loading is necessary for the substrate surface to melt. The second embodiment, delivering the laser energy directly to the substrate surface, takes advantage of the high heat flux rates of the laser, and has the capability of achieving the desired result—that is a molten state at the surface of the material. Unfortunately, by decoupling the deposition process from the melting process, the thermal energy from the flame spray device is allowed time to conduct away from the surface leaving a larger temperature gap to be made up by the laser in order to achieve the molten state. This is a significant drawback of using a continuous coating process with a pulsed surface treatment process, as a significant portion of energy from the flame sprayed particle will always have time to dissipate before the laser pulse. Thus, practical implementation will require melting a sufficiently thick layer of the substrate that will remain molten during a relatively slow pass of the continuous beam of particles generated by the coating process. While this technique may be useful in certain applications, such as very low thermal conductivity materials and thick parts, its thermal efficiency will limit its application.

Pulsed coating methods, such as those described in U.S. Pat. Nos. 6,787,194, 6,749,900, and 6,630,207, differ from conventional coating methods in that the underlying coating process is performed in discrete, repeated cycles. For methods driven by detonations, or other high speed energetic processes, the characteristic time scales for particle arrival/stagnation duration may be on the order of milliseconds or even microseconds. For processes that are typically cycled at frequencies in the 1-500 hz range, low thermal duty cycles may be anticipated, making them advantageous for coating processes that are sensitive to thermal loading. Additionally, the lower thermal loading allows for shorter substrate standoffs, often on the order of 1 cm or less, which further extends the range of application to include smaller parts and more complicated geometric configurations.

However, there remains a need for a coating process that employs a pulsed pre-heating of the surface, that is, the underlying preheating process is performed in discrete, repeated cycles, coupled with a pulsed coating step. In particular, the present inventor has surprisingly discovered that if the pulsed preheating process is timed or synchronized to precede the coating step within a predefined time window, numerous shortcomings of the prior art coating methods may be overcome.

### SUMMARY OF THE INVENTION

Accordingly, the present invention is directed to a method and apparatus for producing coating on a substrate by a synchronized pulsed surface heating and a pulsed material deposition process, or pulsed preheating pulsed coating (PPPC). PPPC takes advantage of the high heat flux rates of pulsed surface heating and the high energy density of a particle stream from a pulsed deposition process in order to facilitate the formation of stronger bond formation between the impacting particles of the coating materials and the substrate material.

In one embodiment, the method of the present invention for producing a coating on a surface of a substrate comprises (1) heating an area of a surface layer of the substrate for a duration of time, and (2) depositing a coating precursor material over the heated area within a time window of the heating step, wherein the temperature of the heated area remains suitable for the coating precursor material to bond with the substrate. Preferably, steps (1) and (2) are repeated numerous times in order to increase the thickness of the coating material, and/or steps (1) and (2) are repeated over different areas of the surface to form a contiguous coating over the surface. In one preferred embodiment, the steps (1) and (2) are repeated over different areas of the surface to form a coated pattern over the surface.

In the context of the present disclosure, one step (1) and one step (2) constitute a pulsed preheating pulsed surface coating (PPPS) cycle and the PPPS cycle is preferably repeated, for example at a frequency of from about 0.1 to about 1,000 Hz.

In each PPPS cycle, the area of the heated surface is larger than area of the coated surface. Alternatively, the preheated surface may be about equal to or smaller than the deposition surface.

According to a preferred embodiment, step (1) of the method of the present invention comprises applying to the substrate at least one type of heat flux selected from the group consisting of laser irradiation, directed electric discharge, plasma, microwave, inductive heating, pulsed detonation, and pulsed combustion. Laser irradiation is especially preferred.

According to a preferred embodiment, the deposition step (2) of the method of the present invention comprises a detonation coating process, a combustion coating process, a precursor injection process, a plasma coating process, a wire arc coating process, or a microwave coating process.

The coating precursor material suitable for the present invention may be selected from the group consisting of metals, ceramics, and cermets, or a combination thereof.

Preferably, at least step (2) is conducted while the substrate is in a low pressure environment or vacuum, or in an inert gas environment. Alternatively, at least step (2) is conducted while the substrate is in ambient air or forced flow air environments.

According to one embodiment of the present invention, precursor materials may be in solid state before impinging into the preheated substrate, or a powder form, in a particulate formulation, in liquid state before impinging into the substrate, or in a gaseous state before impinging into the substrate. The precursor may also be in semi-liquefied state before impinging into the substrate, wherein a part of solid precursor material is liquefied.

Suitable time window between the two steps of the method of the present invention may range from about 0.1 millisecond (ms) to about 1 second, preferably from about 1 ms to about 30 ms. Preferably, the two steps occur simultaneously.

In another embodiment of the present invention, surface heating may occur both before and after the pulsed deposition process.

Suitable methods of depositing the coating material on the surface include injection of precursor material directed toward the heated area of the substrate, or a combustion process that heats and accelerates the precursor material toward the preheated area of the substrate.

The present invention also provides an apparatus for producing a coating on a surface of a substrate comprising: a heating component for heating intermittently an area of the substrate, a depositing component for depositing intermittently a coating precursor material to the substrate, and a controlling component, wherein the operation of the first and the operation of the second component are controlled to operate in a coordinated manner in one or more PPPS cycles each comprising a heating step and a depositing step, and wherein the heating step and the depositing step occur within a predetermined time window.

Preferably, the controlling component controls the heating and depositing components such that preheating of the substrate is synchronized with pulsed deposition of the precursor material over the substrate.

The heating component may comprise a device that generates a type of heat flux selected from the group consisting of laser irradiation, directed electric discharge, plasma, microwave, inductive heating, ultrasonic heating, pulsed detonation, and pulsed combustion. The laser may be selected from the group consisting of a solid state laser, a gas laser, a dye laser, a metal vapor laser, a semiconductor based laser, a free-electron laser, or a Raman laser. In one preferred embodiment, the heat pulse may last from about 1 nanosecond to about 1 millisecond.

According to a preferred embodiment, the heating component of the apparatus according to the present invention comprises a plurality of devices of the same type or different types.

Suitable depositing component for the apparatus of the present invention may comprise one or more of a pulsed detonation coating devices, a pulsed combustion coating device, a pulsed precursor injection device, a pulsed plasma coating device, a pulsed wire arc coating device, and a pulsed microwave coating device. The deposition component may comprise a plurality of pulsed coating devices of the same or different types.

In one embodiment, in the apparatus of the present invention, the heating component and the depositing component each comprises one or more devices of different types.

The apparatus of the present invention preferably is capable of coating in one PPPS cycle an area in the range of about 1 mm² to about 100 cm², preferably in the range of about 10 mm² to about 10 cm² is coated.

The apparatus of the present invention preferably is capable of performing PPPS cycles at a frequency of about 0.1 Hz to about 1,000 Hz.

The present invention in a preferred embodiment further provides an array of two or more devices described above, wherein the devices are configured for simultaneous, sequential or otherwise coordinated manner for coating of one or more substrates.

### BRIEF DESCRIPTION OF THE DRAWINGS

The present invention will now be described in more detail with reference to preferred embodiments of the invention, given only by way of example, and illustrated in the accompanying drawings in which:

FIG. 1 is a schematic illustration of a pulsed preheating-pulsed coating (PPPC) apparatus, in which a pulsed laser preheating using a Nd—YAG laser is used for heating and pulsed detonation coating is used for coating of the precursor materials.

FIG. 2 is schematic illustrations of a pulsed detonation coating device in which fuel and oxidizer are introduced into one section and a suspension of coating material is introduced into another section. Upon ignition of the first section, the detonation products accelerate the suspended coating material toward the exit of the device.

FIG. 3 is a schematic illustration of a PPPC coating apparatus, in which the pulsed preheating is achieved via a laser beam directed through a flexible optical fiber toward the target coating area.

FIG. 4 is a schematic illustration of a PPPC apparatus where the pulsed deposition of precursor material is implemented by intermittent injection of cold particles towards the preheated target area of the substrate.

FIG. 5 is a schematics illustration of PPPC apparatus where pulsed preheating is implemented using a directed electric discharge.

FIG. 6 illustrates a variation for PPPC for coatings inside small tubes and coating at a small standoff distance.

FIG. 7 is an implementation using a beam steering device that allows for laser heating before (leading) and after (trailing) the pulsed coating.

FIG. 8 is an illustration of coating the external surface of a tube using a PPPC apparatus shown in FIG. 2.

FIG. 9 is an illustration of a PPPC shown in FIG. 1 used for net shape forming.

FIG. 10 is an illustration of the device shown in FIG. 1 which forms an array of devices for simultaneous coating of a large surface.

### DETAILED DESCRIPTION OF THE INVENTION

The present invention provides a method for producing a coating on a surface of a substrate, comprising a preheating step synchronized with a deposition step. An area of a surface layer of the substrate is first heated for a period of time, and followed by deposition of a coating precursor material over the heated area within a time window of the heating step, wherein the temperature of the heated area remains suitable for enhancing the bond between the coating precursor material and the substrate.

As used in the context of the present invention, the term “synchronized” means that the preheating step is controlled to occur simultaneously with the coating step, or to precede the coating step within a controlled and well-defined time window. As will be readily recognized by one of ordinary skills in the art, this time window depends on various factors, such as the heat conduction coefficient of the substrate, the power of the device that provides the heating energy, the nature of the coating material, the length of the heating period, etc., and can be determined by those ordinarily skilled in the art. Often the heating time window is about 1 millisecond or less. Shorter or longer time windows can be also used such as those having times of 0.1-100 microseconds or less or 0.1-100 milliseconds or more.

For example, when the main cooling mechanism for an area heated by laser is heat conduction, and if the substrate is metallic, cooling proceeds at a very high rate. Accordingly, molten particle of the coating precursor material from a single event of the depositing step should reach the substrate in 1 to 10 microseconds after the area is preheated by laser irradiation.

For example, a pulsed laser irradiation/preheating step is synchronized with a pulsed detonation coating step. A particular spot on the substrate is heated, e.g. to a molten state with a single or multiple pulses from the laser, and at the same time or within an acceptable, usually narrow time window, a detonation coating device is fired, such that the particles heated and accelerated by detonation arrive at the preheated substrate surface, where both the particles and the surface are in optimal conditions for producing a desirable bond with the substrate surface.

A preheating step and a coating step may be repeated at either a desired rate or at planned intervals while the substrate or/and apparatus are manipulated relative to each other to produce coating over the substrate surface. The steps are repeated numerous times in order to increase the thickness of the coating material, or repeated over different areas of the surface to form a contiguous coating over the surface. One such repeat constitutes a “PPPC cycle.” The PPPC cycles may be repeated at a low or a high frequency, for example at a frequency ranging from about 0.1 to about 1,000 Hz.

It is readily recognized that it is suitable, for the purpose of the present invention, to manipulate either or both of the coating apparatus or the substrate in order to apply coating material over the desired area at the desired standoff (i.e., distance between the coating device and the surface of the substrate) and incident angle.

Depending on the specific embodiment, within each PPPC cycle, the preheating step, or the coating step, or both, may itself comprise more than one firing or pulse of the heating device (e.g. pulsed laser) or coating device (detonation gun).

Thus, the term “pulsed,” as used in the context of the present invention, means that the heating step and the coating step each is performed in discrete steps, which may be repeated. The term “pulsed” may also refer to the nature of the heating step and/or coating step, in that the devices themselves may operate in an intermittent manner (e.g. a pulsed laser or a detonation gun operated in an intermittent manner).

While it is advantageous to have the heating step precede the depositing step, or to occur simultaneously, it is also within the scope of the present invention that the heating may last after the depositing step has concluded, or that the heating step be performed both before and after the arrival of the coating precursor material on to the substrate surface.

Many heating methods and devices are suitable and readily available to those skilled in the art for use in the method of the present invention. For example, surface preheating may be performed with a suitable laser, an electric arc discharge, plasma, microwave, pulsed detonation, pulsed combustion or any other source of pulsed heat flux.

A pulsed laser is preferred as a means for preheating the substrate surface as it allows synchronized irradiation and heating of the surfaces before, after or during particle impingement on the surface, thus assuring that surface of the substrate is molten or at a suitably high temperature when impinged by the coating material to develop satisfactory bonding and often molecular/metallurgical bonding. When successive layers of the coating material are deposited, laser irradiation often allows melting of the previous coating layer and binding of the newly deposited particles and formation of dense coatings.

When a laser is used, it is readily recognized that it may be directed toward the substrate through one or more of optical lenses, mirrors, beam splitters, or flexible optical cables.

In certain situations, heating the substrate may cause changes in material properties, e.g. to make it more conducive to bonding of coated material. Such type of preheating is known as functional preheating. For example, functional preheating may lead to development of a better bond with the coated material. This can happen through one or more of the following mechanisms: higher plastic deformation at elevated temperatures allowing deeper imbedding of coated material; breaking the surface oxide layer that can prevent coating formation; melting the surface that leads to deeper imbedding of coated particle; degassing the surface; creation of a series of intermediate phases that enhance overall bonding, etc. . . . Often, it is desirable that the depth of the substrate material to be preheated be minimized in order to reduce possible negative effects of heating the bulk substrate that may degrade material properties or introduce high thermal stresses to the substrate. The present invention makes it possible to achieve minimization of the preheating depth that is required for development of high quality bonding between the substrate and the coated material. According to preferred embodiments of the present invention, the preheating depth is preferably less than 10 mm, or less than 0.1 mm, or less than 0.01 mm, or less than 0.001 mm.

Depending on the nature of the substrate materials, and the power of the heating device and other factors, the duration of the pulsed surface preheating may last for less than 10 milliseconds, preferably less than 1 millisecond, more preferably less than 100 microseconds, and most preferably less than 100 nanoseconds. However some substrates may require preheating for durations longer than 10 milliseconds.

In accordance with one embodiment of the present invention, the method of the present invention allows the coating precursor material to be transformed to amorphous and/or nano-structured coatings, due to high thermal quench rates accommodated by the pulsed deposition process. It is known that if a liquid metal alloy is cooled fast enough, it may solidify before an organized crystalline and/or grain based structure develops, resulting in “amorphous” states or “metallic glass.” Other material such as cermets and ceramics will also form amorphous or nanocrystalline states when quenched rapidly from molten liquid phase to solid phase. Such amorphous and nanocrystalline materials have remarkable properties including improved mechanical, magnetic properties and corrosion resistance. Depending on the material, a cooling rate may need to be as high as 10⁷ K/s for such amorphous structures to form, however some materials will allow formation of amorphous state at cooling rates lower than 10⁶ K/s or lower than 10⁵ K/s or even lower than 10⁴ K/s.

The method of the present invention is particularly conducive for the formation of such amorphous states. While not willing to be bound by any theory, it is believed that this is due to the high quench rate that is achievable in the PPPC process where the duration of the preheat and deposition part of the cycle can be short as compared with the total time between the cycles. That leads to rapid cooling of the coated area and the substrate temperature can be maintained low. The method of the present invention can achieve a quench rate greater than 10,000,000 K/s, however for some materials achieving quench rate of 10⁵ K/s, 10⁴ K/s, or 10³ K/s is sufficient to form the amorphous sate. Reduction of PPPC cycle frequency, higher raster speed of the PPPC system relative to substrate and forced cooling of the substrate will lead to higher quench rate that may require for formation of amorphous or nanocrystalline state of coated materials.

Conventional thermal spray coating generally uses a standoff of 10 to 30 cm between the coating device outlet and the substrate surface to be coated. According to one embodiment of the present invention, a substrate may be coated at a reduced standoff between the outlet of a PPPC apparatus and the coated surface. In this embodiment, the standoff can be about 5 cm or less and usually ranges from about 2 mm to about 4 cm, and often ranges from about 3 mm to 3 cm, about 4 mm to 2 cm, or about 5 mm to 1 cm. Such reduced standoffs facilitate coating the inside of tubes, especially at corners, and assures uniform material distribution over complex shapes. The PPPC apparatus makes coating at these short standoffs possible because of its small size and because particle are deposited into a molten spot created by laser preheating and do not need to move with high velocity to bond to the surface, avoiding the need for long acceleration distance that increases the bulkiness of the device.

In another embodiment the synchronized pulsed preheating and pulsed coating (PPPC) material deposition apparatus of the present invention is used for depositing coating material to internal or external surfaces for applications where a strong molecular/metallurgical bond is necessary, such as internal or external surfaces of tubes.

In another embodiment PPPC is used for fabricating bulk material parts (net shape manufacturing) where a high degree of homogeneity is necessary. In this embodiment, a freeform surface may be used during the process and subsequently removed to leave behind only the deposited material.

In another embodiment, PPPC may be used inside of a pressure vessel in an elevated (high gas pressure) or evacuated (low gas pressure) environment. Elevated pressure environment combined with gas flow around the substrate will be used to promote substrate cooling and evacuated pressure environment may be used to increase precursor material velocities in the pulsed deposition stage of the process.

A plurality of PPPC devices may be operating concurrently as part of a system. An array of two or more PPPC devices that are operating concurrently may coat different types of materials to either create composite layers or to locally alloy at the surface of the substrate. The number of devices in an array may range from 2 to 9000, preferably between 2 to 100.

The multiple devices are used in concert for one or more of the following reasons: larger coverage area, higher deposition rates, faster processing time, or thermal management. They may be used with different types of coating precursor materials. The array of PPPC devices according to the present invention may be suitably configured for creating a composite material such as: metal/ceramic composite coatings, metal/organic material composite coatings, ceramic/ceramic composite and metal/metal composites, or for forming a coating that comprises an alloy of the different coating precursor materials in the different devices

A PPPC device of the present invention may be integrated and comprises both the substrate preheating and coating deposition functions. A PPPC device of the present invention may be operated concurrently with another non-PPPC coating device.

The pulsed preheating-pulsed coating (PPPC) apparatus of the present invention has utility in applying a wide variety of coating materials to a wide variety of substrates without causing substrate to overheat or warp, and is particularly useful in forming coatings that are fully or mostly fused and molecularly/metallurgically bonded to the substrate. This is achieved by combining preheating of an area of the surface with an apparatus that generates pulsed heat source, such as laser or electrical discharge, with deposit of the coating material onto the preheated area.

Many coating methods and devices are readily available to those skilled in the art and suitable for the present invention. Preferably, coating is done with an intermittent process, for example, using a pulsed coating apparatus such as detonation gun, pulsed cold spray gun or other such device that can generate short duration jets of coating material over the preheated surface.

The method of the present invention may be used with many coating precursor materials. For example Co—Cr—Al—Y alloy powder, WC—Co—Cr powder, Ni—Cr powder, Al—SiC powder, Al—Co—Ce powder, tungsten hexafluoride, zirconium n-butoxide, tantalum V-methoxide and other materials. The coating precursor materials suitable for the present invention preferably are in the form of particles or powders or gaseous or liquid metalorganic compounds. Particles of the coating precursor may be delivered by an injection of cold or heated gas.

In one embodiment, for each PPPC cycle, the preheated surface area may be larger than the coating deposition surface area, or as may be desired, the preheated surface is about equal, or smaller than the deposition surface. The pulsed preheated surface area may be less than about 1 mm², from about 1 mm² to about 1000 mm², or larger than about 1000 mm². The pulsed deposition area may be less than about 1 mm², from about 1 mm² to about 1000 mm², or larger than about 1000 mm².

The substrate may optionally be treated before application of PPPC coatings, e.g. by sand blasting or other substrate preparation methods. In many cases application of the PPPC will not require pretreatment.

The synchronized preheating and coating method of the present invention may be implemented at different scales. For example, when pulsed detonation coating is used in the pulsed coating stage, the exit nozzle diameter may be about 0.2 cm or less, or about 1 cm or less, or about 5 cm or less, or about 10 cm or less. Device total length may be about 1 cm or less, about 5 cm or less, about 20 cm or less, about 50 cm or less, about 100 cm or less or about 200 cm or larger. It is understood by those ordinarily skilled in the art that the coated area is a function of the pulsed detonation coating stage exit nozzle diameter and its stand off from the surface.

Similarly other pulsed coating methods, such as pulsed combustion coating and pulsed cold spray coating, are suitable and may be implemented at different device sizes. It is contemplated that these pulsed coating devices can have characteristic dimensions of about 1 cm or less, about 5 cm or less, about 20 cm or less, about 50 cm or less, about 100 cm or less or about 200 cm or larger. And these pulsed coating devices can have exit nozzle diameter about 0.2 cm or less, about 1 cm or less, about 5 cm or less or about 10 cm or less.

The exit nozzles of these pulsed coating devices may be cylindrical, square, or any other suitable geometrical configuration. More than one pulsed coating device of same or different types may be used to create composite coatings or to cover larger surface area of the substrate.

A multitude of laser types may be used to perform the preheating step of the method of the present invention, including but not limited to Nd:YAG, Ruby, diode or any other laser that can produce a pulse for preheating substrate surface. Pulsed lasers suitable for the present invention may have circular, rectangular, or square beam cross section. More than one laser of the same or different types can be used for pulsed preheating.

Small PPPC devices may be used for coating inner surfaces of tubes with internal diameters about 2 cm and less, about 5 cm and less, about 10 cm and less, about 20 cm and less or more than 20 cm.

PPPC method can be used for coating various types of substrate material such as metals, cermets, plastics, ceramics, plastics or ceramics over metallic. The coating may protect the substrate from wear, erosion or corrosion, or improve substrate heat resistance, increase hardness, increase toughness, or modify (either reduce or increase) friction. By adjusting parameters of the pulsed preheating and pulsed coating, one can obtain coatings that are dense, or porous.

In one embodiment, the PPPC method is implemented while the substrate is in ambient air or a forced flow air environment. Such forced flow environments may be to enhance forced convective cooling of the device and/or substrate material, or for more practical concerns such as ventilation of undeposited particles or combustion byproducts. Alternatively, the PPPC method is implemented while the substrate is in a low pressure environment or vacuum, which allows the coating precursor particles to accelerate to high velocities because of low drag forces at low pressure, leading to high particle impingement velocity and a stronger bond between the substrate and the coated material. It is also sometimes preferable that PPPC is implemented while the substrate is in an inert gas environment, such as Ar, He, or N₂, or a suitable mixture thereof. Immersing the substrate in the inert gas environment will prevent the substrate, coating, and precursor material from oxidation and other reactions with the environment during the preheating and deposition process.

The present invention further provides an apparatus for producing a coating on a surface of a substrate. In one embodiment, the apparatus comprises a heating component for heating intermittently an area of the substrate, a depositing component for depositing intermittently a coating precursor material to the substrate, and a controlling component, wherein the operation of the first and the operation of the second component are controlled to operate in a coordinated manner in one or more PPPS cycles comprising a heating step and a depositing step, and wherein the heating step and the depositing step occur within a predetermined time window.

Suitable heating component and depositing component are as described above and exemplified below. It is readily recognize that many means (e.g. suitable, off-the-shelf control electronics and software) for controlling the heating and depositing components are available and known to those skilled in the art.

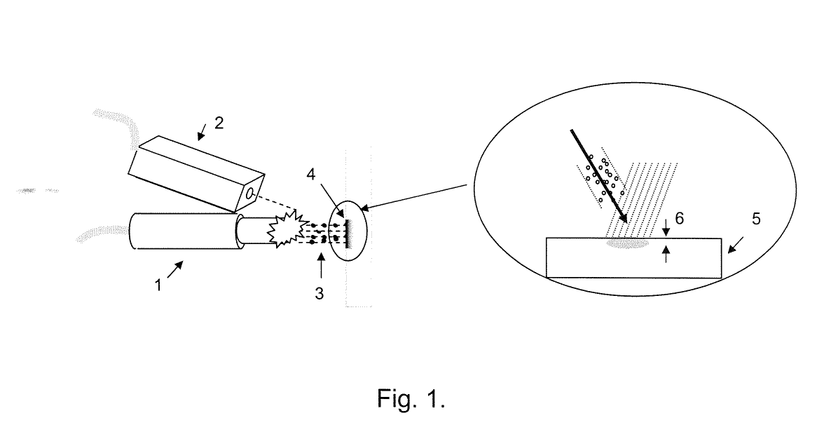

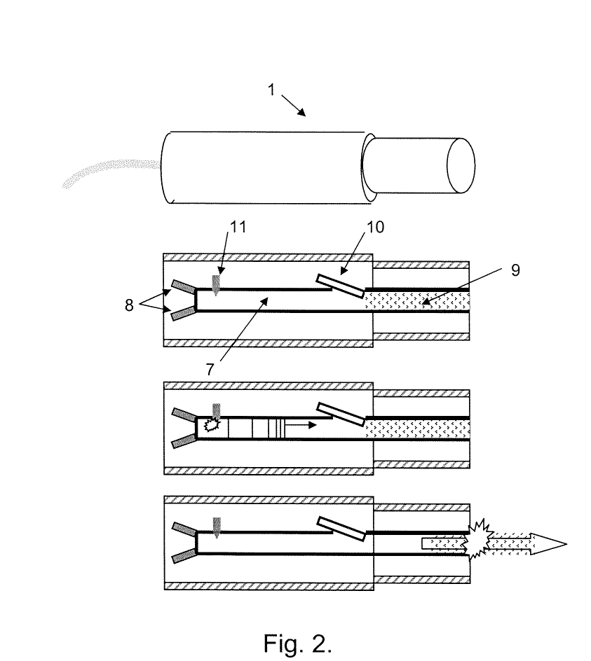

A preferred embodiment of the present invention is illustrated in FIG. 1, showing a pulsed detonation coating apparatus (1), an Nd—YAG pulsed laser (2), a heated and accelerated particle stream (3) impinging on the target area (4) of the substrate material (5). The thermal penetration depth (6) is small relative to the thickness of the substrate (5). An example of the pulsed detonation coating apparatus (1) is shown in FIG. 2a-2d. The apparatus (1) comprises a detonation driver section (7), filled by the propellant inlet valves (8) with a reactive propellant mixture, a detonation driven section (9), filled with a suspension of feedstock particles from a coating delivery injector (10), and a spark plug (11) to initiate the detonation event. Upon initiation, a detonation or deflagration to detonation transition wave develops in the driver section (7) and propagates through the driven section (9) of the apparatus. The exhaust products of the detonation reaction simultaneously heat and accelerate the coating particle suspension in the axial direction, exiting the apparatus.

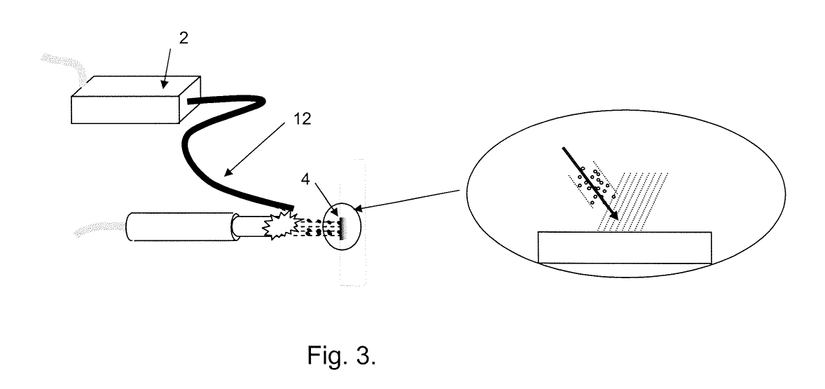

FIG. 3 depicts another embodiment where the output of the ND—YAG pulsed laser (2) is transmitted through a flexible optical fiber (12) toward the substrate target area (4). Such an approach allows the laser source to be kept apart from the rest of the PPPC device and would be particularly advantageous for scenarios that require the PPPC device to be manipulated.

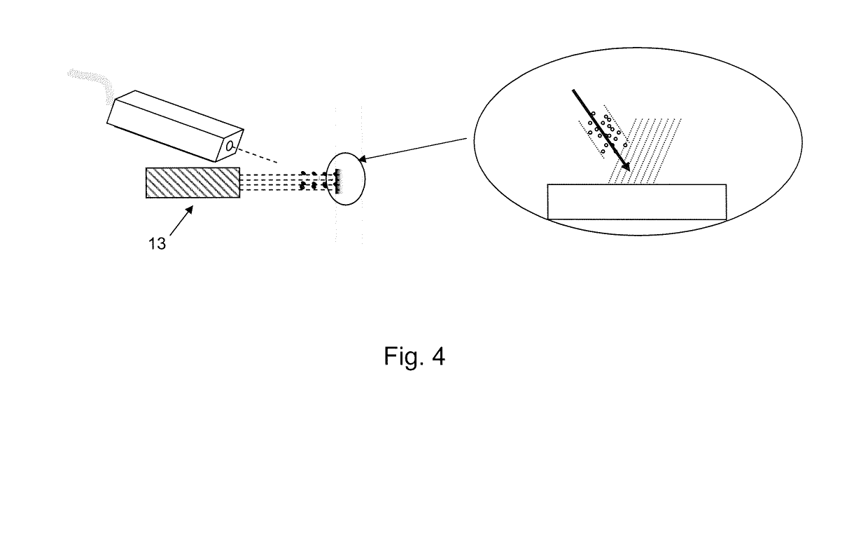

FIG. 4 depicts another embodiment where the particles to be coated are accelerated but not substantially heated by the kinetic coating apparatus (13). Certain classes of material may be capable of coating successfully without substantial heating during the acceleration process, allowing a non-thermal coating apparatus to be used for the PPPC process.

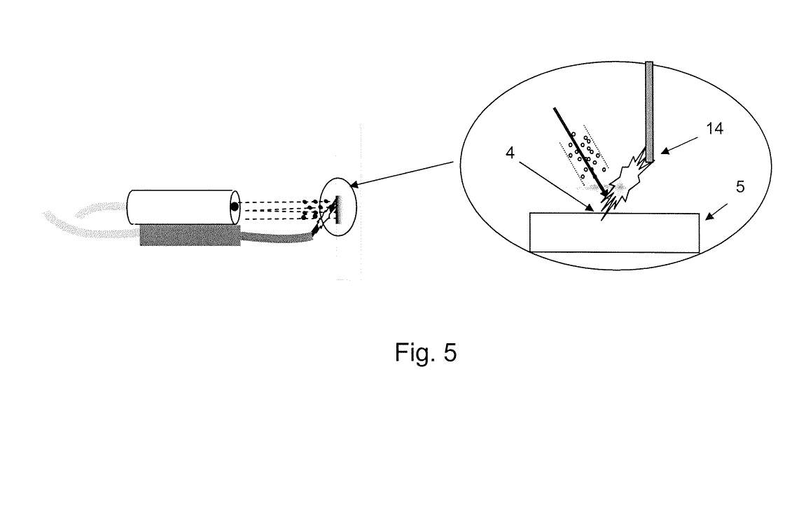

FIG. 5 illustrates another embodiment where the substrate surface is preheated by a directed electric discharge. In this embodiment the substrate (5) can act as the cathode as a properly oriented anode (14) directs an electrical discharge to the surface of the target area (4). The substrate (5) could also act as the anode, with the cathode now protruding from the device (14) to draw the electrical discharge from the anode.

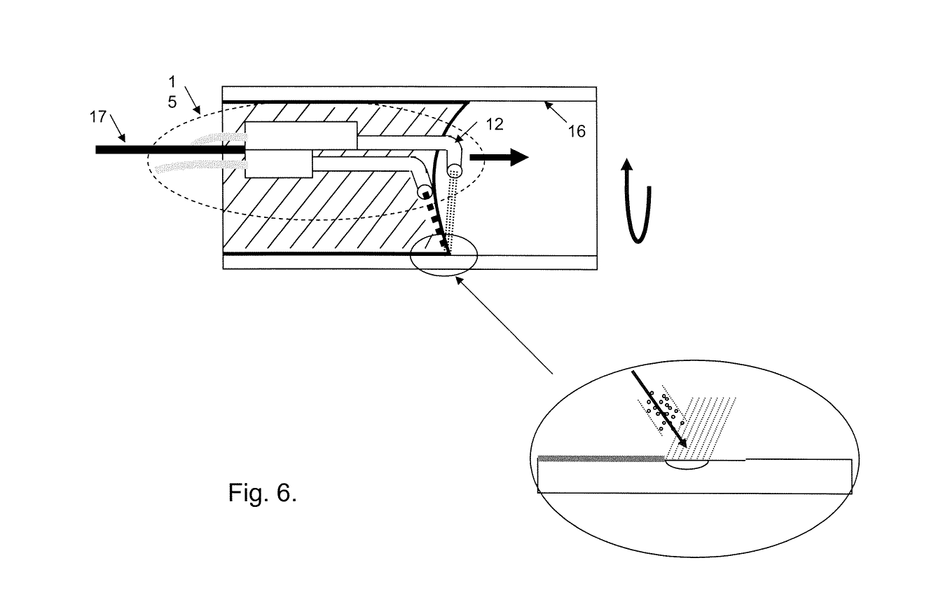

FIG. 6 illustrates another embodiment where an Inner Diameter (ID) PPPC device (15) of the present invention is used to coat the internal surface of a tube (16). In this figure, a traversing arm (17) translates the device (15) axially while the tube (16) is rotated about the center axis. The minimum diameter of the tube is generally limited by the necessary stand off for the device, as well as the dimensions of the device. The device (15) is preferentially shifted off-axis (although still parallel) in order to maximize standoff distance. In this example, the laser is guided through a flexible optical fiber (12).

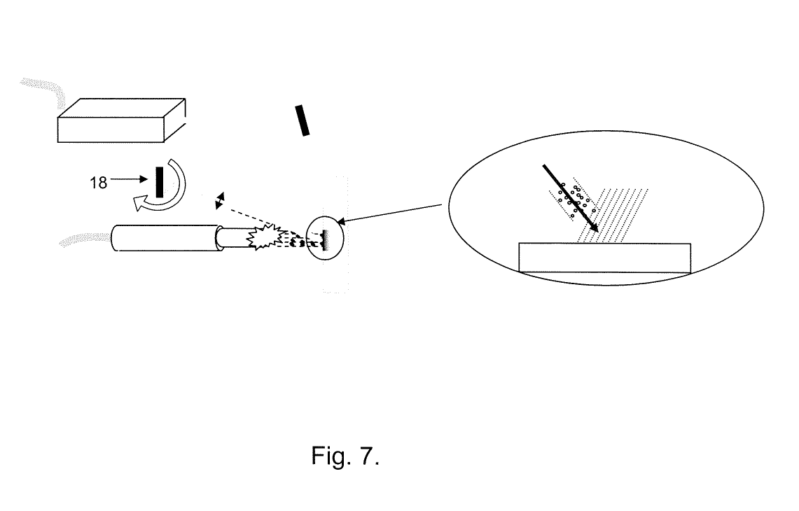

FIG. 7 illustrates another embodiment where a beam steering device (18) is used to manipulate the laser pulse such that a pulse is delivered both before (leading) and after (trailing) the pulsed coating deposition. For a fast enough pulsed laser, steering of the beam would not be necessary, as the target would essentially be unmoved immediately before and after the deposition process. For more practical laser systems, however, it may be necessary to incorporate the beam-steering device such that the preheat shot may be immediately before the deposition, and the later shot would occur at some characteristic time later, corresponding to a characteristic translational distance for a part being manipulated relative to the apparatus.

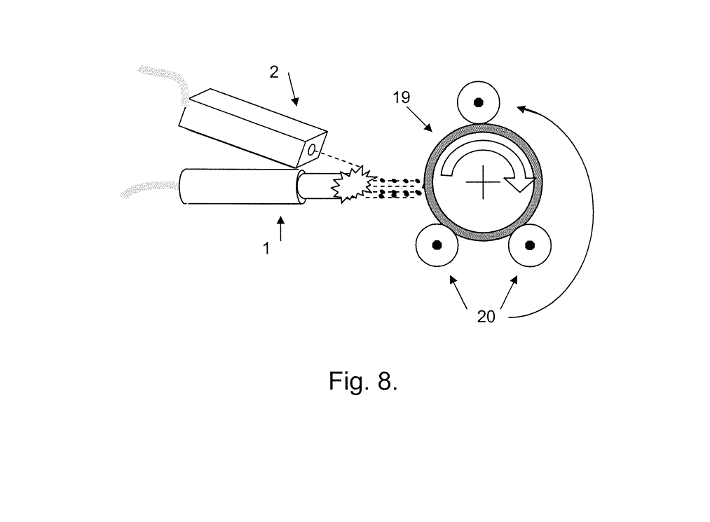

FIG. 8 illustrates an embodiment of the present invention where the PPPC apparatus, comprising a pulsed coating device (1) and a pulsed laser (2), is used to coat the external surface of a tube (19). In the current configuration, for example, the tube to be coated is being supported and rotated about its centerline by three adjacent wheels (20). Either the device (1,2) or the rotational apparatus (19, 20) may be translated relative to the other in coating the 2-D surface.

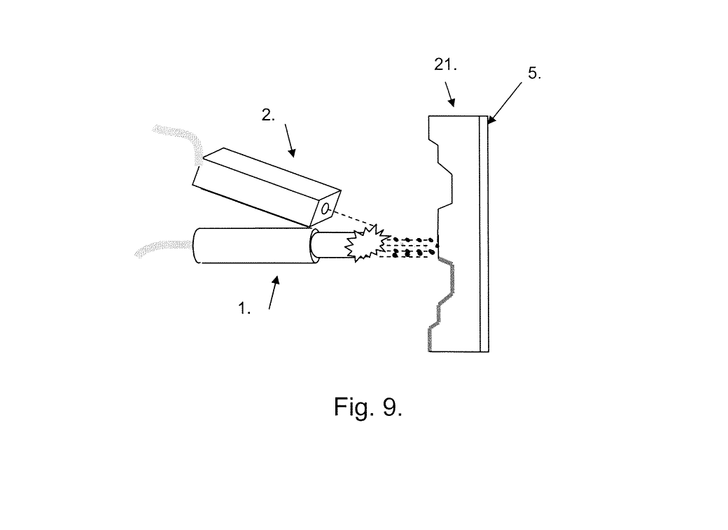

FIG. 9 illustrates an embodiment of the present invention where a PPPC apparatus, comprising a pulsed coating device (1) and a pulsed laser (2), is used in net shape forming. In this example, the base substrate layer (5) is used solely as a template for the subsequent, spatially resolved build up of coated material (21). After completion, this base substrate layer (5) may be removed, with the resultant part created entirely from PPPC deposited material.

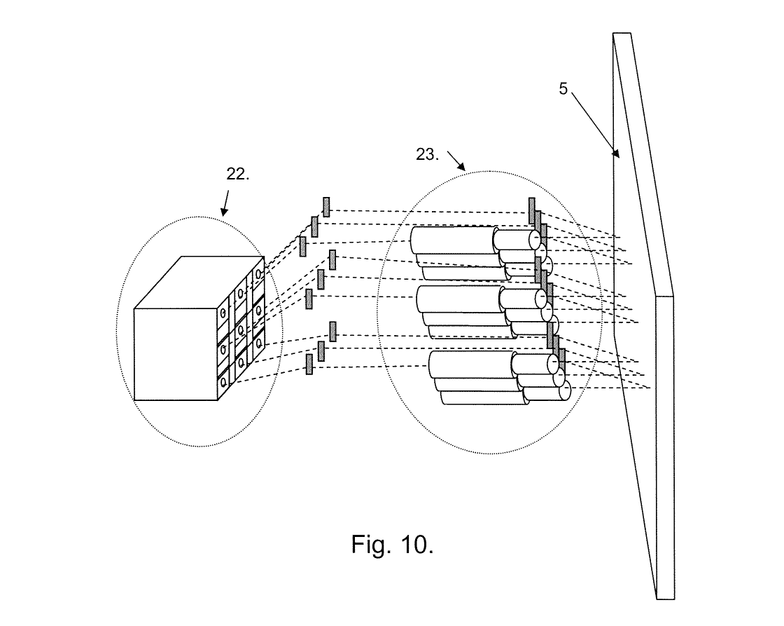

FIG. 10 illustrates an embodiment of the present invention where multiple PPPC devices are configured in an array for operating concurrently. For this example the laser devices (22) are maintained away from the remainder of the system (23) and each laser pulse is optically directed to the corresponding target on the substrate (5).

### EXAMPLES

### Example 1

A PPPC device is constructed using a pulsed detonation coating gun, a diode-pumped Nd—YAG laser, a flexible optical fiber for directing the laser beam, a robotic arm for manipulation of the gun and optical fiber output, an apparatus for mounting of the base substrate, and custom control electronics and software. The optical fiber and the coating gun are configured such that they translate together and at all times are directed at the same spot on the base material, which is located at a preferential distance from the exit of the coating gun, which is between 1 to 10 inches. The laser is focused such that the spot diameter on the base substrate is equal to the coated area diameter, which for this example is between 5 mm to 20 mm diameter.

This device is used to coat a stainless steel part. The coating material precursor is a cermet tungsten carbide cobalt in a powdered form with an average particle size of about 20 micron.

A single sequence of the operation consists of a pulse of laser irradiation “preheating” the to-be-coated area of the base substrate, followed closely by a detonation event and subsequent acceleration of a single shot of heated tungsten carbide cobalt particles in the direction of the base substrate toward the area preheated by the laser. This sequence is repeated at a frequency of 40 Hz, while the robotic arm manipulates the coating gun and laser output relative to the surface of the base material. The translational speed is determined such that the coated area of a subsequent single sequence overlaps with the coated area of the preceding sequence by 50%, which for 5 mm diameter spot size would be 10 cm/s. The coating process is continued and repeated until a suitable thickness coating is achieved over the desired surface area.

The foregoing description and examples have been set forth merely to illustrate the invention and are not intended to be limiting. Since modifications of the disclosed embodiments incorporating the spirit and substance of the invention may occur to persons skilled in the art, the invention should be construed broadly to include all variations falling within the scope of the appended claims and equivalents thereof. Furthermore, the teachings and disclosures of all references cited herein are expressly incorporated in their entireties by reference.

What is claimed is:

1. A method for producing a coating on a surface of a substrate, the method comprising the steps of:
(1) heating an area of a surface layer of the substrate for a duration of time, and
(2) depositing a coating precursor material over the heated area within a time window of the heating step, wherein the temperature of the heated area remains suitable for the coating precursor material to bond with the substrate.

2. The method according to claim 1, wherein the steps (1) and (2) are repeated numerous times in order to increase the thickness of the coating material.

3. The method according to claim 1, wherein the steps (1) and (2) are repeated over different areas of the surface to form a contiguous coating over the surface.

4. The method according to claim 3, wherein the steps (1) and (2) are repeated numerous times in order to increase the thickness of the coating material.

5. The method according to claim 1, wherein the steps (1) and (2) are repeated over different areas of the surface to form a coated pattern over the surface.

6. The method according to claim 1, wherein one step (1) and one step (2) constitute a PPPS cycle and the PPPS cycle is repeated.

7. The method according to claim 6, wherein the PPPS cycle is repeated at a frequency of from about 0.1 to about 1,000 Hz.

8. The method of claim 6, wherein in each PPPS cycle, the area of the heated surface is larger than area of the coated surface.

9. The method of claim 1, wherein the preheated surface is about equal or smaller than the deposition surface.

10. The method according to claim 1, wherein step (1) comprises applying to the substrate at least one type of heat flux selected from the group consisting of laser irradiation, directed electric discharge, plasma, microwave, inductive heating, pulsed detonation, and pulsed combustion.

11. The method according to claim 10, wherein step (1) comprises applying laser irradiation to the substrate.

12. The method according to claim 1, wherein the deposition comprises a detonation coating process, a combustion coating process, a precursor injection process, a plasma coating process, a wire arc coating process, or a microwave coating process.

13. The method according to claim 1, wherein the coating precursor material is selected from the group consisting of metals, ceramics, cermets and plastics, or a combination thereof.

14. The method according to claim 1, wherein at least step (2) is conducted while the substrate is in a low pressure environment or vacuum.

15. The method according to claim 1, wherein at least step (2) is conducted while the substrate is in an inert gas environment.

16. The method according to claim 1, wherein at least step (2) is conducted while the substrate is in ambient air or forced flow air environments.

17. The method according to claim 1, wherein the precursor material is in solid state before impinging into the preheated substrate.

18. The method according to claim 1, wherein a feedstock material used for the precursor is initially in a powder form, or in a particulate formulation.

19. The method according to claim 1, wherein the precursor material is in liquid state before impinging into the substrate.

20. The method according to claim 1, wherein the precursor material is in a gaseous state before impinging into the substrate.

21. The method according to claim 1, wherein the precursor is in semi-liquefied state before impinging into the substrate, wherein a part of solid precursor material is liquefied.

22. The method according to claim 1, wherein the time window ranges from about 0.1 millisecond (ms) to about 1 second.

23. The method according to claim 1, wherein the time window ranges from about 1 ms to about 30 ms

24. The method according to claim 1, wherein said surface heating occurs both before and after, the pulsed deposition process.

25. The method according to claim 1, wherein the step (2) comprises an injection of precursor material directed toward the heated area of the substrate, or a combustion process that heats and accelerates the precursor material toward the preheated area of the substrate.

26. An apparatus for producing a coating on a surface of a substrate comprising:
a heating component for heating intermittently an area of the substrate,
a depositing component for depositing intermittently a coating precursor material to the substrate, and
a controlling component,
wherein the operation of the first and the operation of the second component are controlled to operate in a coordinated manner in one or more PPPS cycles each comprising a heating step and a depositing step, and wherein the heating step and the depositing step occur within a predetermined time window.

27. The apparatus, according to claim 26, wherein the pulsed preheating of the substrate is synchronized with pulsed deposition of the precursor material over the substrate.

28. The apparatus according to claim 26, wherein the heating component comprises a device that generates a type of heat flux selected from the group consisting of laser irradiation, directed electric discharge, plasma, microwave, inductive heating, ultrasonic heating, pulsed detonation, pulsed detonation and pulsed combustion.

29. The apparatus according to claim 28, wherein the heating component comprises a laser selected from the group consisting of a solid state laser, a gas laser, a dye laser, a metal vapor laser, a semiconductor based laser, a free-electron laser, or a Raman laser.

30. The apparatus according to claim 28, wherein the heat flux generated by the device is a pulse that lasts from about 1 nanosecond to about 1 millisecond.

31. The apparatus according to claim 28, wherein the heating component comprises a plurality of devices of the same type or different types.

32. The apparatus according to claim 26, wherein the depositing component comprises one or more of a pulsed detonation coating device, a pulsed combustion coating device, a pulsed precursor injection device, a pulsed plasma coating device, a pulsed wire arc coating device, a pulsed microwave coating device.

33. The apparatus according to claim 26, wherein the heating component and the depositing component each comprises one or more devices of different types.

34. The apparatus according to claim 26, wherein in one PPPS cycle an area in the range of about 1 mm² to about 100 cm² is coated.

35. The apparatus according to claim 34, wherein in one PPPS cycle an area in the range of about 10 mm² to about 10 cm² is coated.

36. The apparatus according to claim 26, wherein the PPPS cycle is repeated at a frequency of about 0.1 Hz to about 1,000 Hz.

37. An array of two or more devices according to claim 26, wherein the devices are configured for simultaneous, sequential or otherwise coordinated manner for coating of one or more substrates.

38. The method according to claim 1, wherein a feedstock material used for the precursor is initially in a gaseous form.

39. The method according to claim 1, wherein a feedstock material used for the precursor is initially in a liquid form.
